(19) United States
(12) Patent Application Publication
(10) Pub. No.: US 2019/0082534 A1
(43) Pub. Date: Mar. 14, 2019

(54) INTERCONNECT FRAMES FOR SIP MODULES

(71) Applicant: Apple Inc., Cupertino, CA (US)

(72) Inventors: Lan H. Hoang, Los Gatos, CA (US); Chang Liu, San Jose, CA (US)

(73) Assignee: Apple Inc., Cupertino, CA (US)

(21) Appl. No.: 15/699,946

(22) Filed: Sep. 8, 2017

(51) Int. Cl. H05K 1/14; H05K 1/11; H05K 1/18; H05K 1/02

(52) U.S. Cl. CPC H05K 1/144; H05K 1/111; H05K 1/181; H05K 1/115; H05K 1/0216; H05K 3/0014; H05K 2201/042; H05K 2201/09809; H05K 2201/10303; H05K 2203/107; H05K 2201/047

(57) ABSTRACT

Frames and other structures for system-in-package modules that may allow components on boards in the modules to communicate with each other.

### BACKGROUND

The number of types of electronic devices that are commercially available has increased tremendously the past few years and the rate of introduction of new devices shows no signs of abating. Devices, such as tablet, laptop, netbook, desktop, and all-in-one computers, cell, smart, and media phones, storage devices, portable media players, navigation systems, monitors, and others, have become ubiquitous.

The functionality of these devices has likewise greatly increased. This in turn has led to increased complexity inside of these electronic devices. At the same time, the dimensions of these devices have become smaller. For example, smaller and thinner devices are becoming more popular.

This increasing functionality and decreasing size have necessitated the use of space-efficient circuit manufacturing techniques. As one example, system-in-package (SIP) modules and other similar structures may be used to increase an electronic device's functionality while reducing space consumed in the device. Reducing the space consumed in a device allows additional functionality to be included in the device, allows the device to be smaller, or a combination thereof.

These system-in-package modules may include electronic devices or components placed on a board and then sealed and encapsulated in a plastic or other material. Other modules may include electronic devices or components placed on a first board and electronic devices or components placed on a second board. But it may be difficult for components on the two boards to communicate in this configuration.

Thus, what is needed are structures for modules that may allow components on separate boards in the modules to communicate with each other.

### SUMMARY

Accordingly, embodiments of the present invention may provide structures for system-in-package modules that may allow components on boards in the modules to communicate with each other.

An illustrative embodiment of the present invention may provide a system-in-package module having two printed circuit boards facing each other. Specifically, one or more circuits or components may be located on a surface of a first printed circuit board. One or more circuits or components may be located on a surface of a second printed circuit board. The surfaces of these printed circuit boards may be encapsulated, either together or separately. The encapsulated portions may be adjacent such that the surfaces of the boards face each other with the components and encapsulation between them. One or more intermediate layers that may be used for shielding, grounding, heat spreading, or other reasons, may be located between the boards. The one or more intermediate layers may be formed of conductive metal or other material.

In conventional system-in-package modules, communication between a top printed circuit board and a bottom printed circuit board may be difficult. Accordingly, these and other embodiments of the present invention may provide a frame or interposer that may be located between the top printed circuit board and the bottom circuit board. This frame may be located around edges of one or both of the printed circuit boards. The frame may include other portions that are not located around edges of either printed circuit board. For example, the frame may include portions that traverse from one edge of a frame to another edge of a frame along a middle of a printed circuit board. These frames may provide mechanical support, shielding, signal pathways including radio-frequency and other high-speed signal pathways, printed circuit board alignment, and other features to the SIP modules.

It should be noted that while the interconnect structures described above are well-suited to forming system-in-package modules, in these and other embodiments of the present invention, other types of electronic devices may be formed using these techniques. Embodiments of the present invention may be used at different levels in the manufacturing of a SIP module. For example, a SIP module may be formed of one or more other sub-modules, and these embodiments of the present invention may be used in one or more of these sub-modules. The SIP module itself may be formed by employing one or more embodiments of the present invention.

In various embodiments of the present invention, contacts, interconnect paths, and other conductive portions of SIP modules may be formed by stamping, metal-injection molding, machining, micro-machining, ink jet, 3-D printing, aerosol jet printing, or other type of printing or manufacturing process. The conductive portions may be formed of stainless steel, steel, copper, copper titanium, aluminum, phosphor bronze, or other material or combination of materials. They may be plated or coated with nickel, gold, or other material. The nonconductive portions may be formed using injection or other molding, ink-jet, 3-D, aerosol-jet, or other type of printing, machining, or other manufacturing process. The nonconductive portions may be formed of silicon or silicone, rubber, hard rubber, plastic, nylon, liquid-crystal polymers (LCPs), plastic, epoxy, resin, or other nonconductive material or combination of materials. The printed circuit board or other appropriate substrates used may be formed of FR-4, BT or other material. Printed circuit boards may be replaced by other substrates, such as flexible circuit boards, in many embodiments of the present invention, while flexible circuit boards may be replaced by printed circuit boards in these and other embodiments of the present invention.

Embodiments of the present invention may provide SIP modules that may be located in various types of devices, such as portable computing devices, tablet computers, desktop computers, laptops, all-in-one computers, wearable computing devices, cell phones, smart phones, media phones, storage devices, portable media players, navigation systems, monitors, power supplies, adapters, remote control devices, chargers, and other devices.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates an intermediate layer for a system-in-package module according to an embodiment of the present invention;

FIG. 2 illustrates a system-in-package module according to an embodiment of the present invention;

FIG. 3 illustrates a method of encapsulating a system-in-package module according to an embodiment of the present invention;

FIG. 4 illustrates a portion of a frame according to an embodiment of the present invention;

FIG. 5 illustrates a portion of a system-in-package module according to an embodiment of the present invention;

FIG. 6 illustrates a system-in-package module according to an embodiment of the present invention;

FIG. 7 illustrates a portion of a system-in-package module according to an embodiment of the present invention;

FIG. 8 illustrates a portion of a frame according to an embodiment of the present invention;

FIG. 9 illustrates a portion of a system-in-package module according to an embodiment of the present invention;

FIG. 10 illustrates another portion of a frame according to an embodiment of the present invention;

FIG. 11 illustrates another portion of a frame according to an embodiment of the present invention;

FIG. 12 illustrates a portion of a system-in-package module according to an embodiment of the present invention;

FIG. 13 illustrates a portion of a frame according to an embodiment of the present invention;

FIG. 14 illustrates a portion of a frame according to an embodiment of the present invention;

FIG. 15 illustrates a method of manufacturing a portion of a frame according to an embodiment of the present invention;

FIG. 16 illustrates a top view of a shielded signal path in a portion of a frame according to an embodiment of the present invention;

FIG. 17 illustrates a side cross-section view of a portion of the frame of FIG. 16;

FIG. 18 illustrates a side view of a portion of the frame of FIG. 16;

FIGS. 19A-19I and 20A-20B illustrate methods of manufacturing a high-speed path according to an embodiment of the present invention; and

FIGS. 21A-21D illustrate a method of forming interconnect according to an embodiment of the present invention.

### DESCRIPTION OF EXEMPLARY EMBODIMENTS

An illustrative embodiment of the present invention may provide a system-in-package module having two printed circuit boards facing each other. Specifically, one or more circuits or components may be located on a surface of a first printed circuit board. One or more circuits or components may be located on a surface of a second printed circuit board. The surfaces of the ease printed circuit boards may be encapsulated, either together or separately. The encapsulated portions may be adjacent such that the surfaces of the boards face each other with the components and encapsulation between them. One or more intermediate layers that may be used for shielding, grounding, heat spreading, or other reasons may be located between the boards. An example is shown in the following figures.

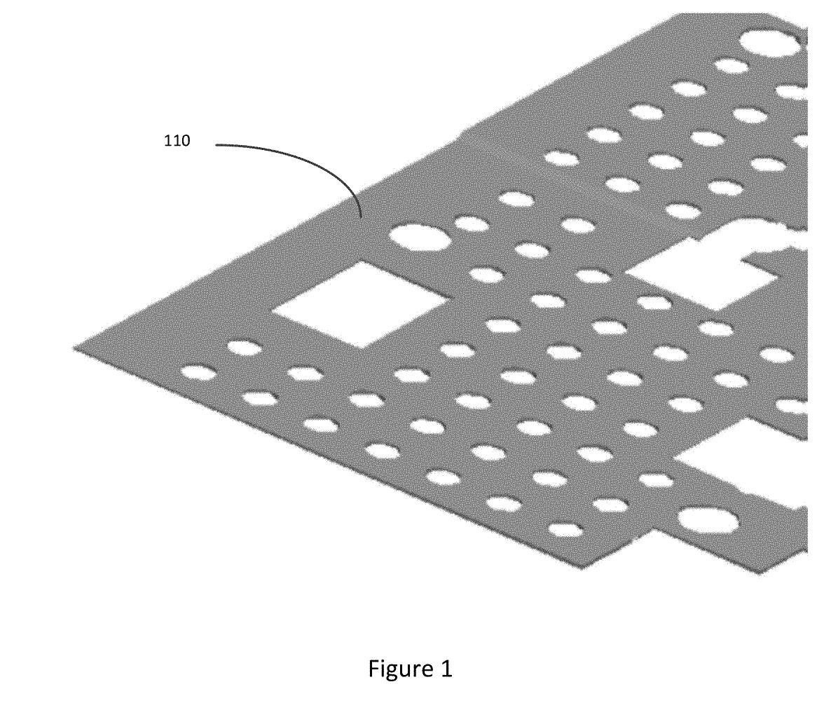

FIG. 1 illustrates an intermediate layer for a system-in-package module according to an embodiment of the present invention. Intermediate layer 100 may be formed of metal or other conductive material. Intermediate layer 110 may be formed by die cutting, stamping, printing, or other technique. Intermediate layer may be used for shielding, grounding, heat spreading, or other reasons in a system-in-package module. Intermediate layer 110 may include several openings and passages through which encapsulation material may flow during assembly.

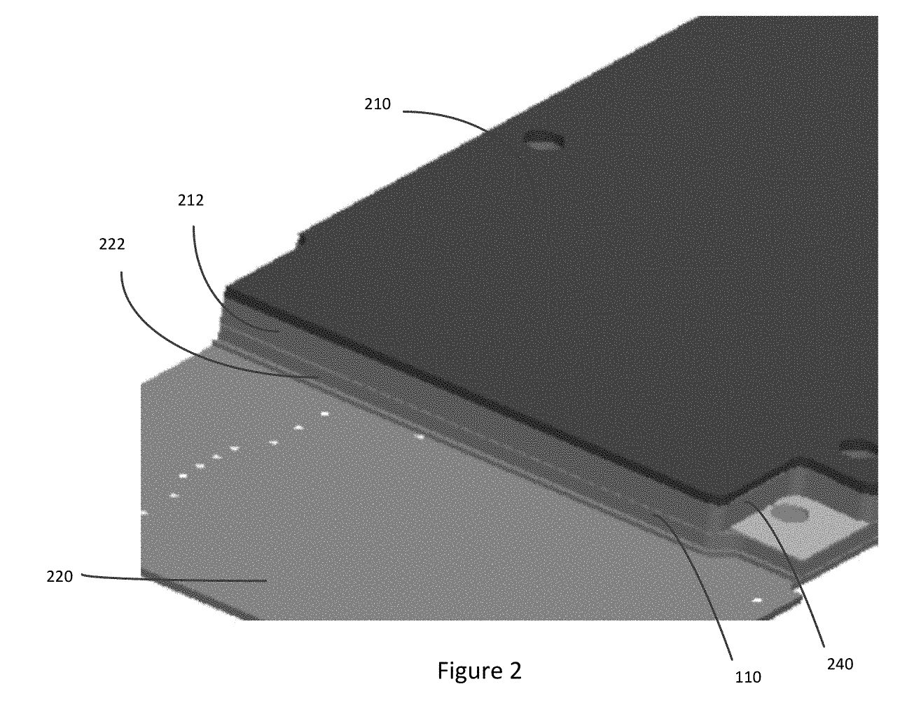

FIG. 2 illustrates a system-in-package module according to an embodiment of the present invention. This example may include top printed circuit board 210 and bottom printed circuit board 220. Intermediate layer 110 may be located between top printed circuit board 210 and bottom printed circuit board 220. Layers of encapsulation material 212 and 222 may be formed between intermediate layer 110 and top printed circuit board 210 and intermediate layer 110 and bottom printed circuit board 220. Intermediate layer 110 may have openings (shown in FIG. 1) to allow encapsulation material 212 and 222 to flow though intermediate layer 110 during assembly. After encapsulation, the system-in-package module may be trimmed along the edges 240 of the encapsulation material. This may be done using a laser, computer numerical control (CNC) machine, router, or other appropriate tool.

Edges 240 of the system-in-package module may be printed or plated with silver, gold, or other material. The plating may then be insulated for use in an electronic device. Masking or other techniques may be used in applying the plating and insulating materials. In these and other embodiments of the present invention, these layers may be used as shielding. They may also be used as antennas, particularly where the system-in-package module includes wireless circuitry. Passive components, such as resistors, capacitors, inductors, and other components may be formed using these and other layers along edges 240 and elsewhere in and on the system-in-package module.

In various embodiments of the present invention, various types of encapsulation materials and methods may be used. An example is shown in the following figure.

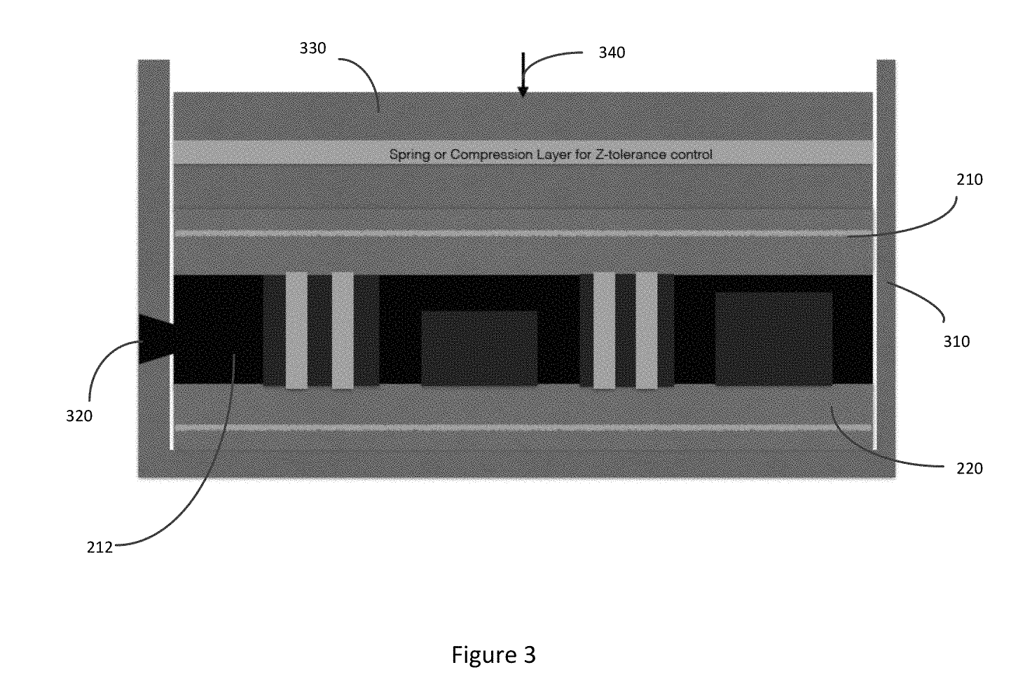

FIG. 3 illustrates a method of encapsulating a system-in-package module according to an embodiment of the present invention. In this example, a system-in-package module may include top printed circuit board 210 and bottom printed circuit board 220, which may be located in tool 310. Tool 310 may have an exit location 320. Encapsulation material 212 may be placed between top printed circuit board 210 and bottom printed circuit board 220. A force 340 may be applied to a spring or compression layer 330. Spring or compression layer may push top printed circuit board 210 towards bottom printed circuit board 220. Excess encapsulation material 212 may exit tool 310 at exit location 320.

In the above example, edges 240 of the system-in-package module may need to be trimmed, plated, and insulated. Also, communication between top printed circuit board 210 and bottom printed circuit board 220 may be difficult. Accordingly, these and other embodiments of the present invention may provide frames, interposers, or other structures that may be located between top printed circuit board 210 and bottom printed circuit board 220. A frame may be located around edges of one or both of the printed circuit boards. That is, where a top printed circuit board 210 and a bottom printed circuit board 220 may have an overlapping area, the frame may follow and be along some or all of an outline of the overlapping area. The frame may include other portions that are not located around edges of either printed circuit board. For example, the frame may include portions that traverse from one edge of a frame to another edge of a frame along a middle of a printed circuit board, that is, through the overlapping area. These frames may provide mechanical support, shielding, signal pathways, printed circuit board alignment, and other features for the SIP modules. An example of one such frame is shown in the following figure.

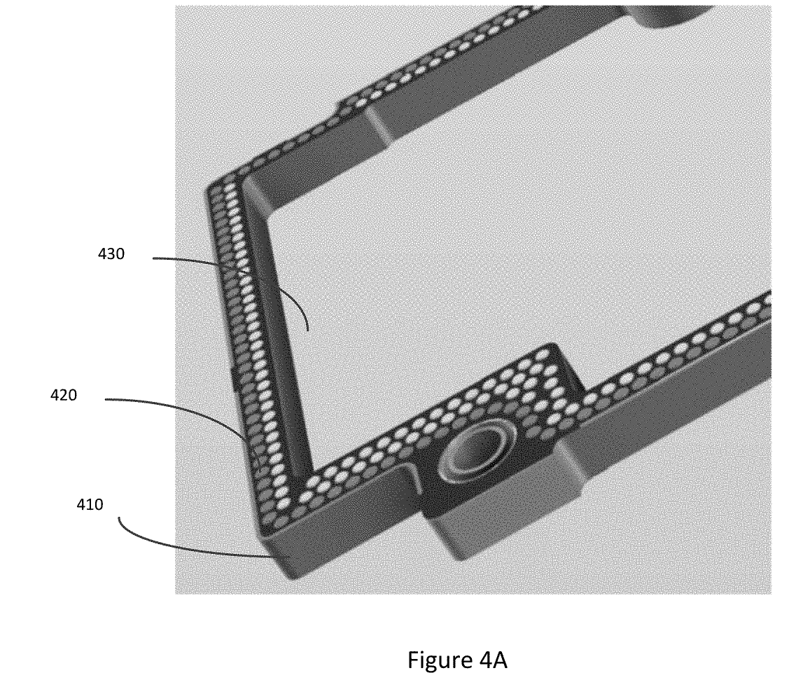

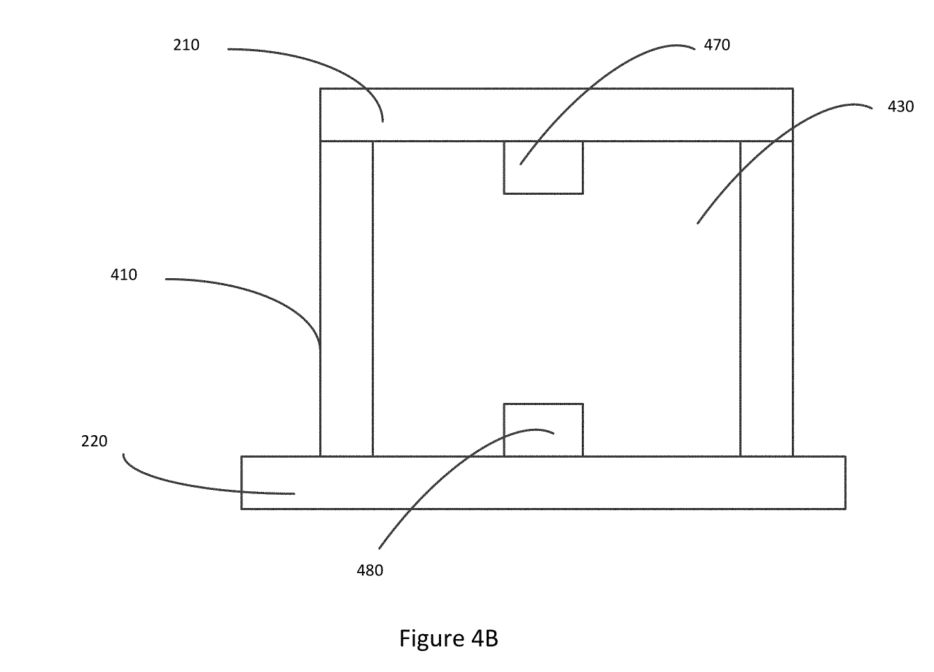

FIG. 4 illustrates a portion of a frame according to an embodiment of the present invention. Frame 410 may be made from a printed circuit board. Frame 410 may be formed using a CNC machine, router or other tool. A number of through holes may be drilled through frame 410 and filled to provide vias 420. Vias 420 may align with and electrically and physically connect to pads, contacts, or vias on top printed circuit board 210 and bottom printed circuit board 220 to facilitate communication between circuitry on those boards.

As with the other frames shown herein or other frames consistent with embodiments of the present invention, frame 410 may be sized to fit along edges of either or both top printed circuit board 210 or bottom printed circuit board 220 (shown in FIG. 2.) That is, frame 410 (and the other frames shown here) may follow an edge of a first board, where the edge of a first board is coincident or overlapping with an edge of the second board. In this way, the frame remains between the boards and at (or near) an outside edge of the SIP module such that space inside the SIP module is maximized and is not wasted. Also or instead, these frames may have intermediate portions that travers between edges of either or both top printed circuit board 210 or bottom printed circuit board 220. These intermediate portions may be used to isolate various circuits in the SIP modules.

As with the other frames shown herein or other frames consistent with embodiments of the present invention, frame 410 may be located around components on facing surfaces of top printed circuit board 210 and bottom printed circuit board 220 (shown in FIG. 2.) In this example, a first component (not shown) on a surface of top printed circuit board 210 may be in region 430 of frame 410. Similarly, a second component (not shown) on a surface of bottom printed circuit board 220 may be in region 430 of frame 410. The first component may connect through a first trace in top printed circuit board 210 to a first contact on the surface of top printed circuit board 210. The first contact may connect to a via 420 in frame 410 (or other interconnect in other frames.) The via may connect the first contact to a second contact on a surface of the bottom printed circuit board 220. A second trace in the bottom printed circuit board 220 may connect the second contact to the second component. The region 430 may be encapsulated in each of the frames shown herein and that are consistent with embodiments of the present invention.

As with the other frames shown herein or other frames consistent with embodiments of the present invention, only a portion of frame 410 is shown. Frame 410, and the other frames herein, may formed a closed loop, or more than one closed loop, or they may have one or more open ends.

As with the other frames shown herein or other frames consistent with embodiments of the present invention, frame 410 may be formed of a printed circuit board. This printed circuit board may, as with the other printed circuit boards such as top printed circuit board 210 and bottom printed circuit board 220, be formed of various layers with various traces on the layers and vias interconnecting traces on the various layers. These vias and layers may provide for a lateral translation of the signal path through the frame 410.

In these and other embodiments of the present invention, frames may be formed of other materials. For example, frames may be formed using laser direct structuring (an LDS frame), injection molded plastic, or other material. An example is shown in the following figure.

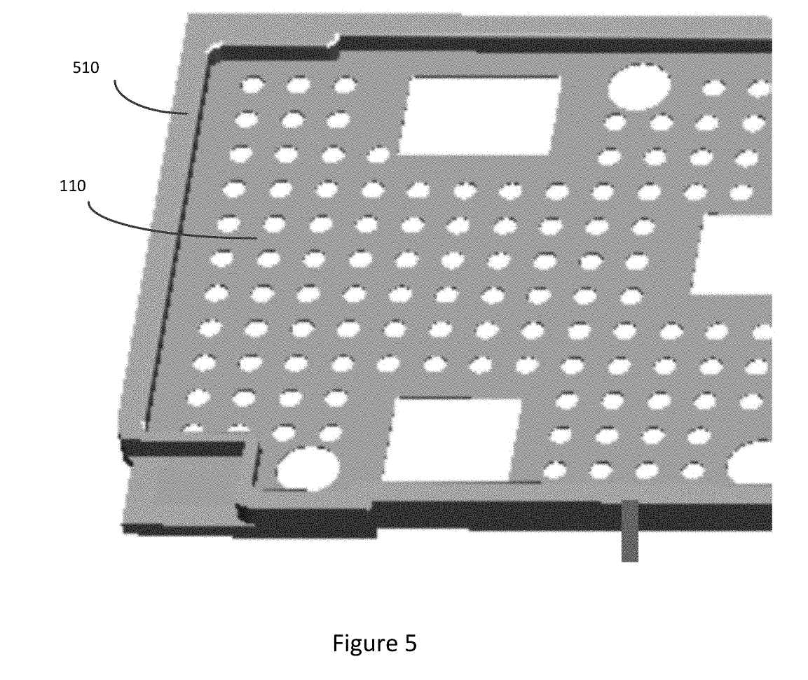

FIG. 5 illustrates a portion of a system-in-package module according to an embodiment of the present invention. In this example, intermediate layer 110 may be framed by frame 510. Frame 510 may be an LDS frame, it may be made of injection molded plastic, or it may be made of another material.

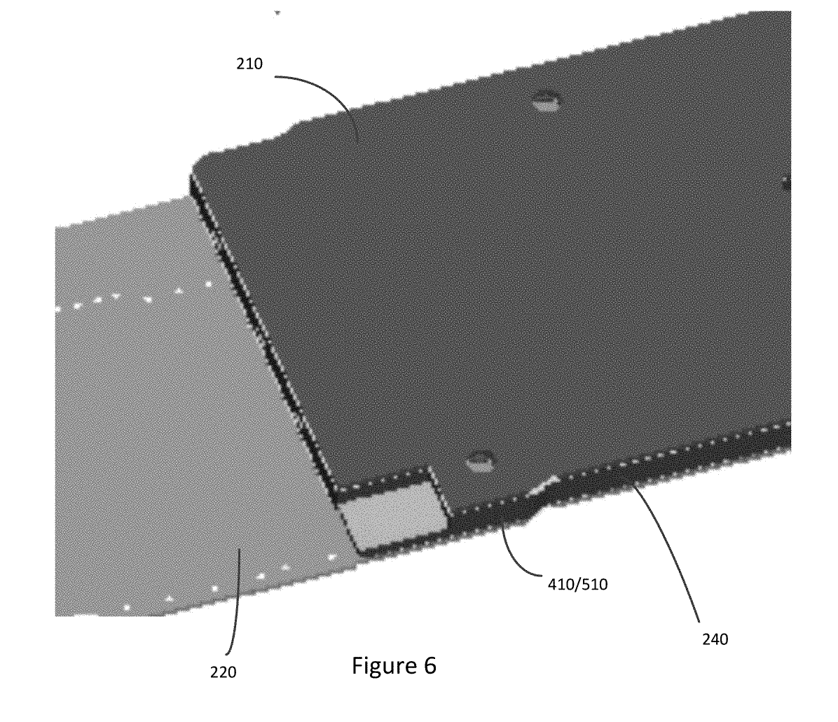

FIG. 6 illustrates a system-in-package module according to an embodiment of the present invention. In this example, either of frames 410 or 510 (shown in FIG. 4 and FIG. 5), or any of the other frames described here or that are consistent with embodiments of the present invention, may be located between top printed circuit board 210 and bottom printed circuit board 220. During manufacturing, top printed circuit board 210 and bottom printed circuit board 220 may be soldered to frame 410 or 510. The space between top printed circuit board 210 and bottom printed circuit board 220 may be filled with an encapsulation material. If needed, edges 240 of the system-in-package module may be trimmed, for example with a CNC machine, router, laser, or other tool.

In these and other embodiments of the present invention, other features may be included on a frame. An example is shown in the following figure.

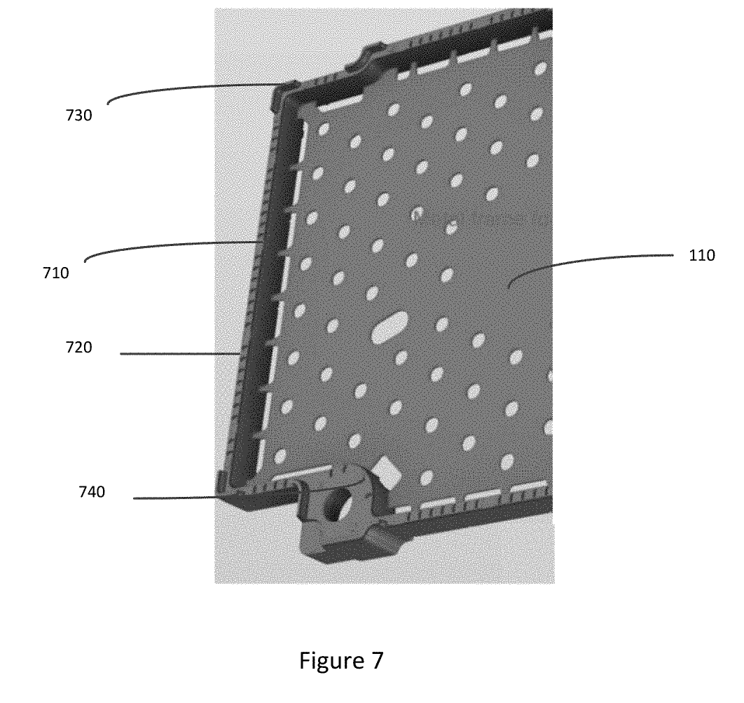

FIG. 7 illustrates a portion of a system-in-package module according to an embodiment of the present invention. In this example, intermediate layer 110 may be framed by frame 710. Frame 710 may be an LDS frame, it may be formed of plastic, printed circuit board, or other material. Frame 710 may include a number of dimples 720 to increase the friction between frame 710 and top printed circuit board 210 and bottom printed circuit board 220 (shown in FIG. 6.) Frame 710 may further include alignment features 730. Alignment features 730 may be placed along an outside edge of frame 710 to improve the alignment of top printed circuit board 210 and bottom printed circuit board 220 to frame 710. Frame 710 may further include hard stops 740 that may be used to accurately set a thickness of the encapsulation material and therefor the thickness of the resulting system-in-package module. For example, frame 710 may be pliable and compressible. Using a hard stop 740 may prevent this compression and maintain a thickness of frame 710 during assembly.

In these and other embodiments of the present invention, still other features may be included on a frame. Examples are shown in the following figure.

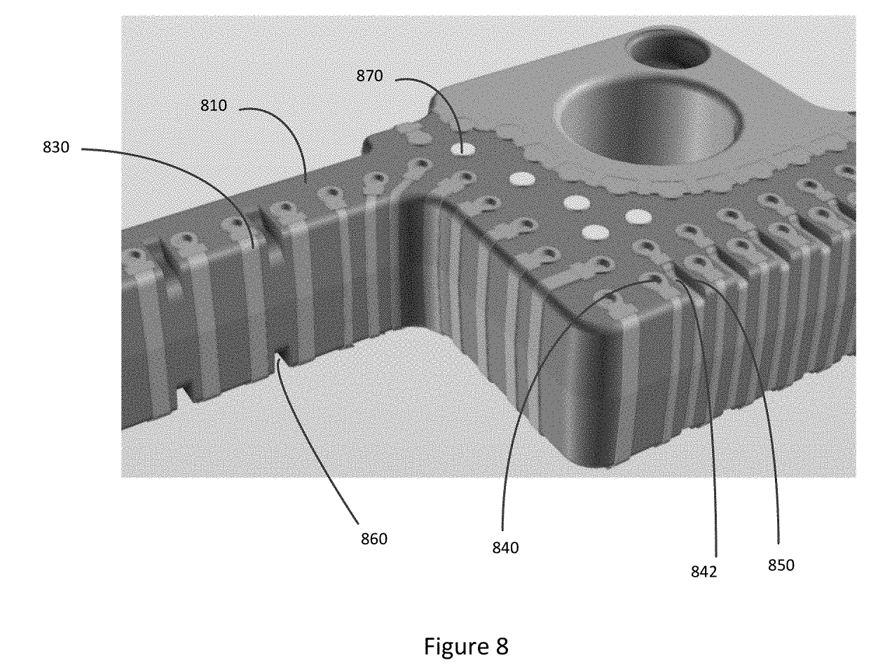

FIG. 8 illustrates a portion of a frame according to an embodiment of the present invention. In this example, frame 810 may be an LDS or other type of frame. Interconnect traces 830 may be formed along sides of frame 810 to provide signal, power, and ground routes between top printed circuit board 210 and bottom printed circuit board 220 (shown in FIG. 2.) Mechanical slots 860 may be included along top and bottom inside edges of frame 810. Mechanical slots 860 may help with adhesion between frame 810 and top printed circuit board 210 and bottom printed circuit board 220. Specifically, encapsulation material 212 (shown in FIG. 2) may fill mechanical slots 860. The mechanical slots 860 and encapsulation material in the mechanical slots 860 may form interlocking features that may secure frame 810 in place. Additional escape slots 850 may also be included. These slots may act similar to mechanical slots 860 to improve adhesion. Escape slots 850 may also increase a spacing between solder pads 840 and traces 842, thereby reducing the possibility that they are shorted together by solder during assembly. Pins 870 may be molded or inserted into frame 810. Pins 870 may provide additional signal, power, and ground routes between top printed circuit board 210 and bottom printed circuit board 220. Pins 870 may also provide mechanical strength to frame 810. Pins 870 may also provide a hard stop (similar to hard stops 740 in FIG. 7) that may be used to accurately set a thickness of the encapsulation material and therefor the thickness of the resulting system-in-package module. For example, frame 810 may be pliable and compressible. Using pins 870 as hard stops may prevent this compression and maintain a thickness of frame 810 during assembly.

In these and other embodiments of the present invention, interconnect between components on top printed circuit board 210 and bottom printed circuit board 220 may be included on a LDS frame. Examples are shown in the following figures.

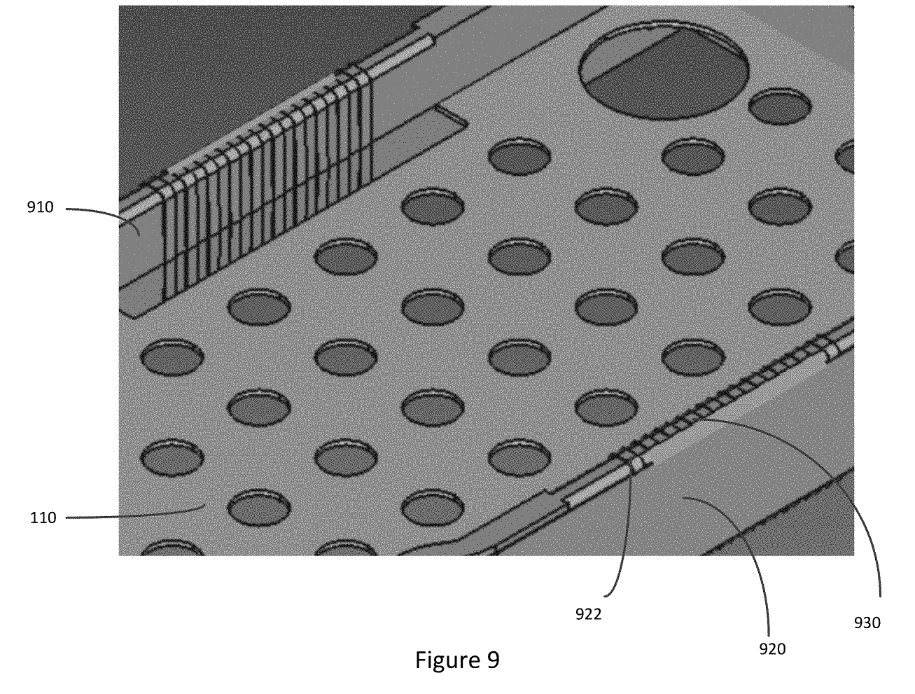

FIG. 9 illustrates a portion of a system-in-package module according to an embodiment of the present invention. In this example frame 910 may be formed around intermediate layer 110. Frame 910 may be an LDS or other frame. An outside edge of frame 910 may be shielded with metallic layer 920. Contacts 922 may connect to shielding layer 920 and provide a ground path between top printed circuit board 210 and bottom printed circuit board 220. Signal paths 930 may also be provided from top printed circuit board 210 to bottom printed circuit board 220.

In these examples, metal interconnect may be formed on LDS frame 910 by a laser abrading the desired conductive pads. The desired conductive paths may then be plated to complete frame 910.

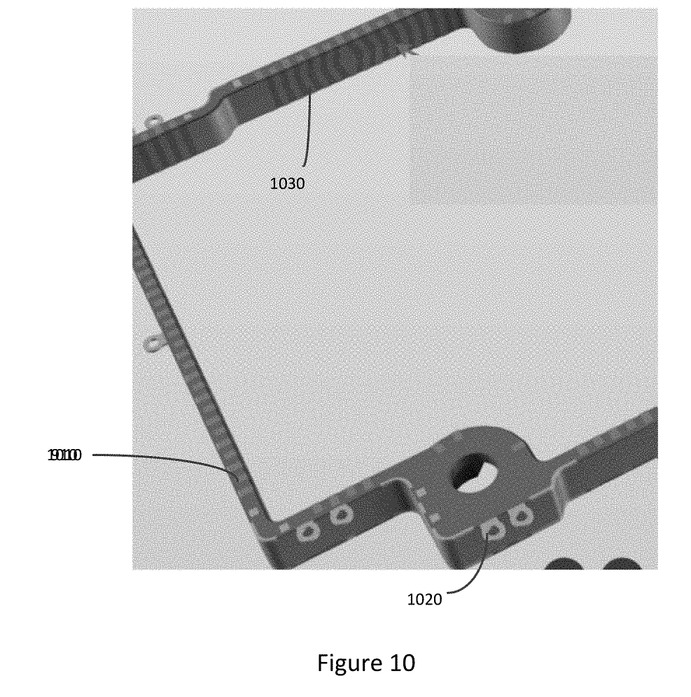

FIG. 10 illustrates another portion of a frame according to an embodiment of the present invention. Frame 1010 may include signal paths 1030, which may route from a top of frame 1010 to a bottom of frame 1010. As illustrated, interconnect or signal paths 1030 do not need to be formed using straight lines, but may form any pattern and may also be used to provide a lateral translation in the signal path. Tabs 1020 may connect to ground or shield regions of frame 1010. Tabs 1020 may be soldered to either or both top printed circuit board 210 and bottom printed circuit board 220 during assembly.

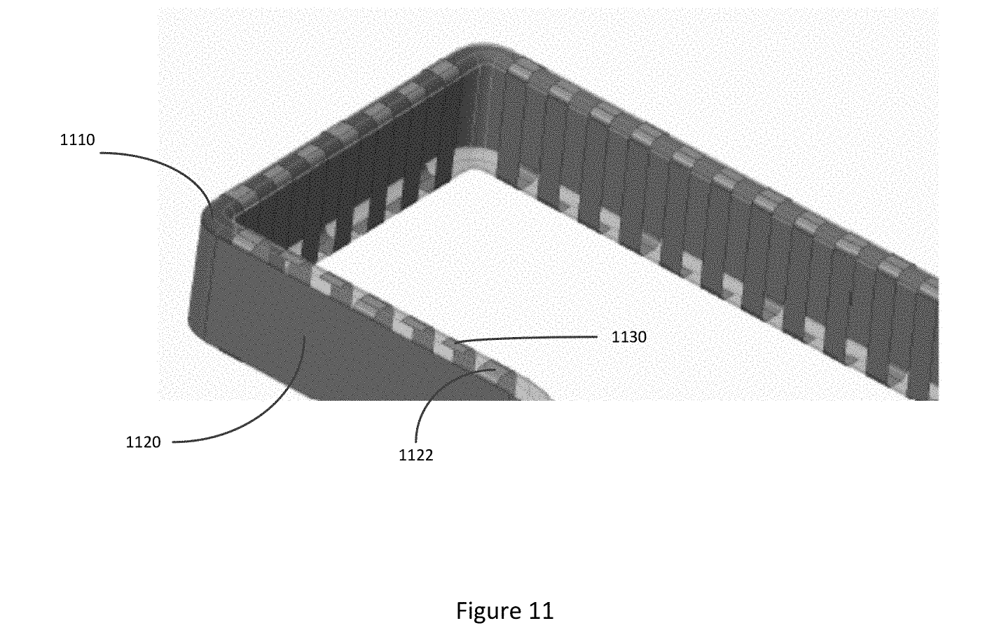

FIG. 11 illustrates another portion of a frame according to an embodiment of the present invention. In this example, frame 1110 may include outside shielding 1120. Contacts 1122 may connect to shielding 1120 and may provide ground pathways between top printed circuit board 210 and bottom printed circuit board 220. Signal paths 1130 may also be included from a top of frame 1110 to a bottom of frame 1110.

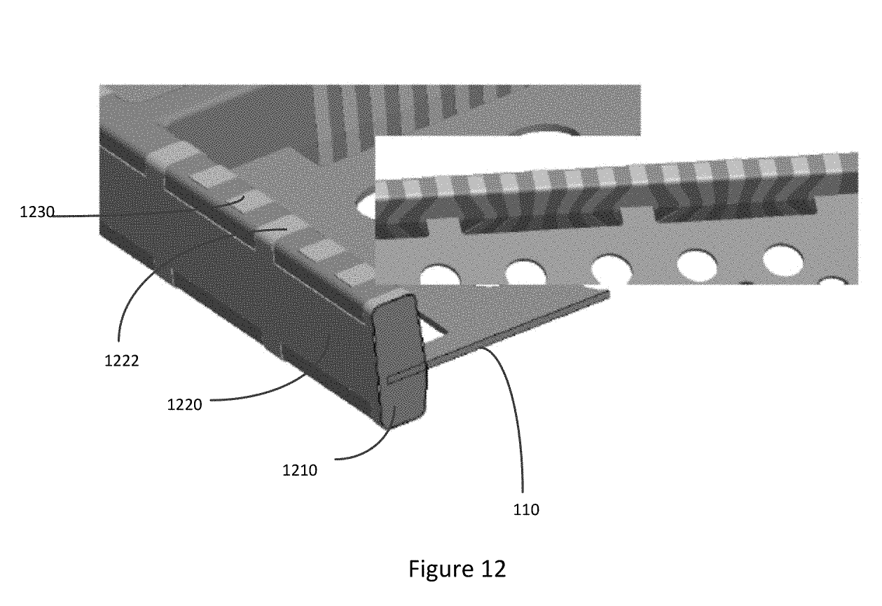

FIG. 12 illustrates a portion of a system-in-package module according to an embodiment of the present invention. In this example, intermediate layer 110 may be surrounded by frame 1210. An outside edge of frame 1210 may be plated with ground shield 1220. Contacts 1222 may provide ground connections between top printed circuit board 210 and bottom printed circuit board 220. Signal pathways 1230 may be used for communications between circuits on top printed circuit board 210 and bottom printed circuit board 220.

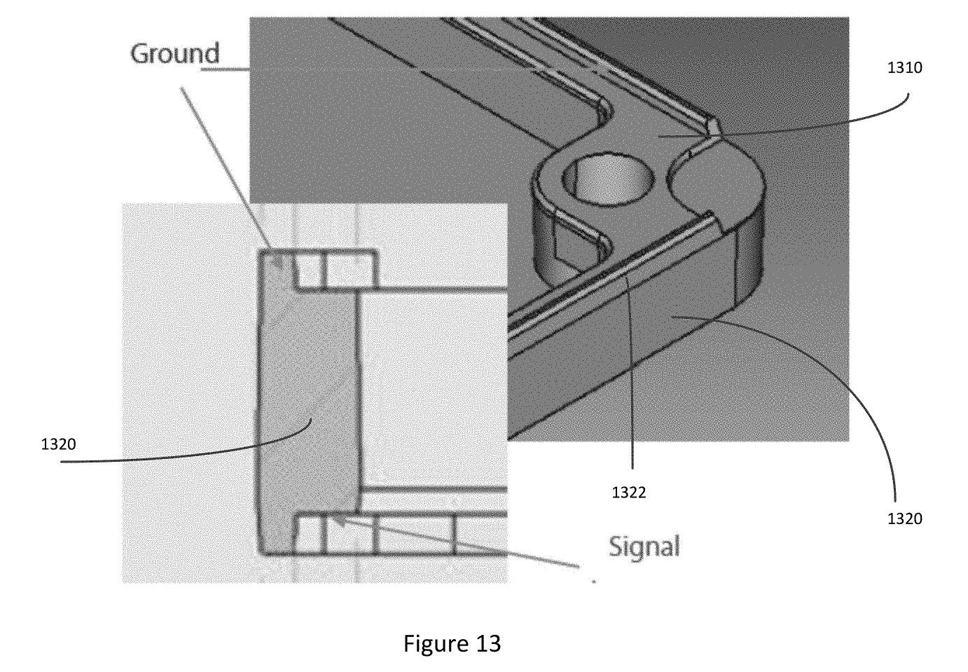

FIG. 13 illustrates a portion of a frame according to an embodiment of the present invention. In this example, an outside edge of frame 1310 may be formed of metal 1320. This outside edge of metal 1320 may include lip 1322. Lip 1322 may be used in aligning top printed circuit board 210 and bottom printed circuit board 220 to frame 1310. In this example, the relatively thick metal 1320 may provide mechanical support for frame 1310, as well as shielding, grounding, heat dissipation, and other purposes.

In various embodiments of the present invention, other types of structures may be used for signal pathways. Examples are shown in the following figures.

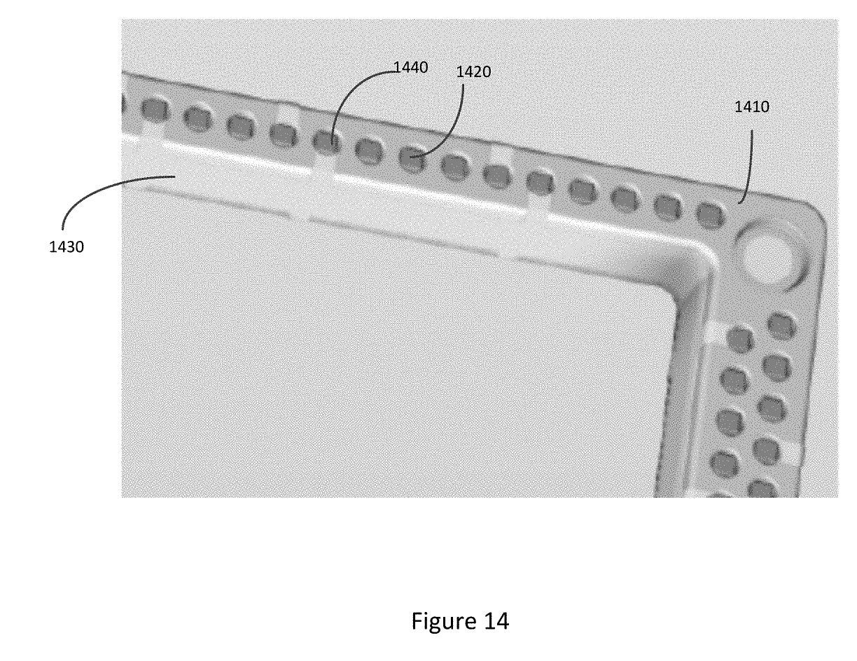

FIG. 14 illustrates a portion of a frame according to an embodiment of the present invention. In this example, metallic pins 1420 may be inserted into LDS or plastic frame 1410. Shielding 1430 may connect to one or more of the pins 1420, shown here as pin 1440. Pins 1420 may be used to convey signals between top printed circuit board 210 and bottom printed circuit board 220, while pins 1440 may provide ground paths between the boards. The frame of FIG. 14 may be formed in various ways. An example is shown in the following figure.

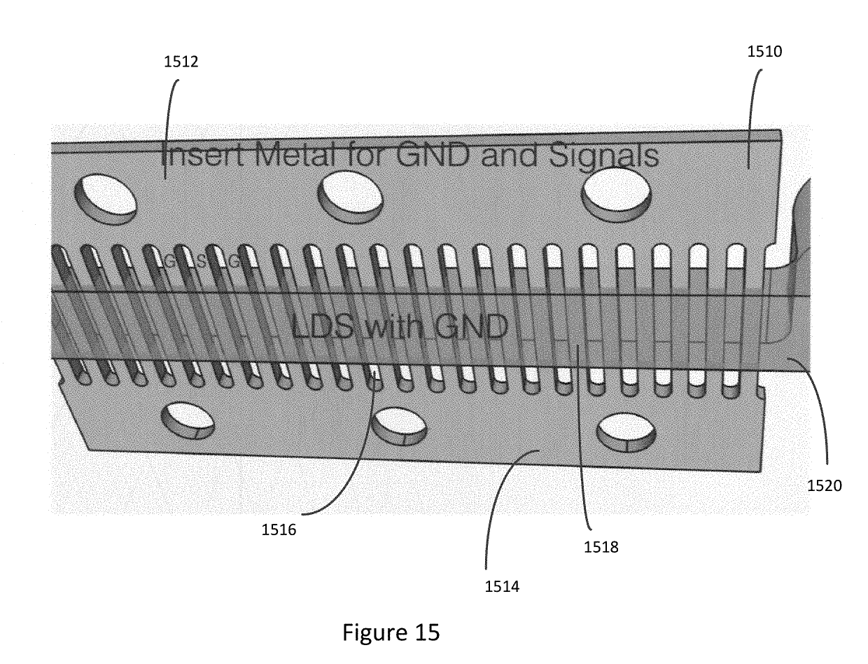

FIG. 15 illustrates a method of manufacturing a portion of a frame according to an embodiment of the present invention. In this example, metal plate 1510 may include openings 1516 defining pins 1518. LDS or other plastic may be molded around pins 1518 to form frame 1520. A top section 1512 and bottom section 1514 of metal plate 1510 may be removed, thereby leaving behind a plastic or LDS frame 1520 with embedded pins 1518. In these and other embodiments of the present invention, pins 1518 may instead, or also, be inserted into frame 1520 after molding. For example, a tool used to form frame 1520 may leave holes in frame 1520 such that pins 1518 may be mechanically pushed into the holes.

In these and other embodiments of the present invention, it may be desirable to transfer very high-speed or radio-frequency signals from top printed circuit board 210 to bottom printed circuit board 220. Examples of frames that may be used for this are shown in the following figures.

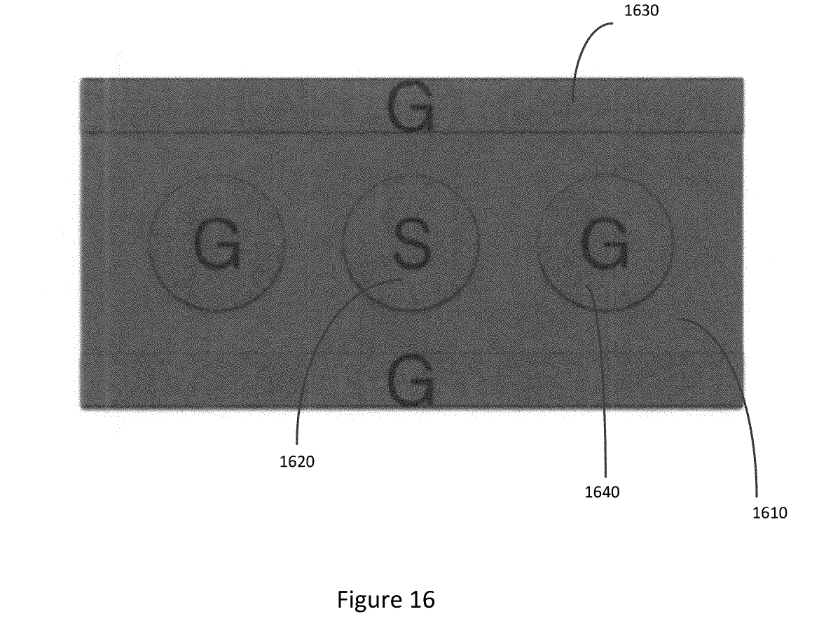

FIG. 16 illustrates a top view of a shielded signal path in a portion of a frame according to an embodiment of the present invention. Frame 1610 may include pins 1620 and 1640. Pins 1620 may convey a signal, while pins 1640 may be grounded. Ground shield layers 1630 may also be included on sides of frame 1610. In this way, a signal on signal pin 1620 may be shielded.

In these and other embodiments of the present invention, it may be desirable to improve a strength of these contacts. An example of how this may be done is shown in the following figure.

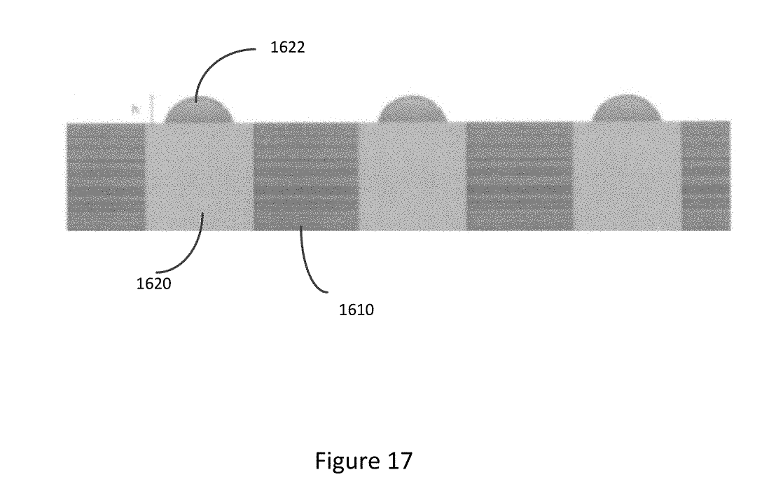

FIG. 17 illustrates a side cross-section view of a portion of the frame of FIG. 16. In this example, frame 1610 may include signal pin 1620 as before in FIG. 16. A domed structure 1622 may be formed, deposited, or otherwise located on a top surface of pin 1620. This domed structure 1622 may improve a strength of pin 1620.

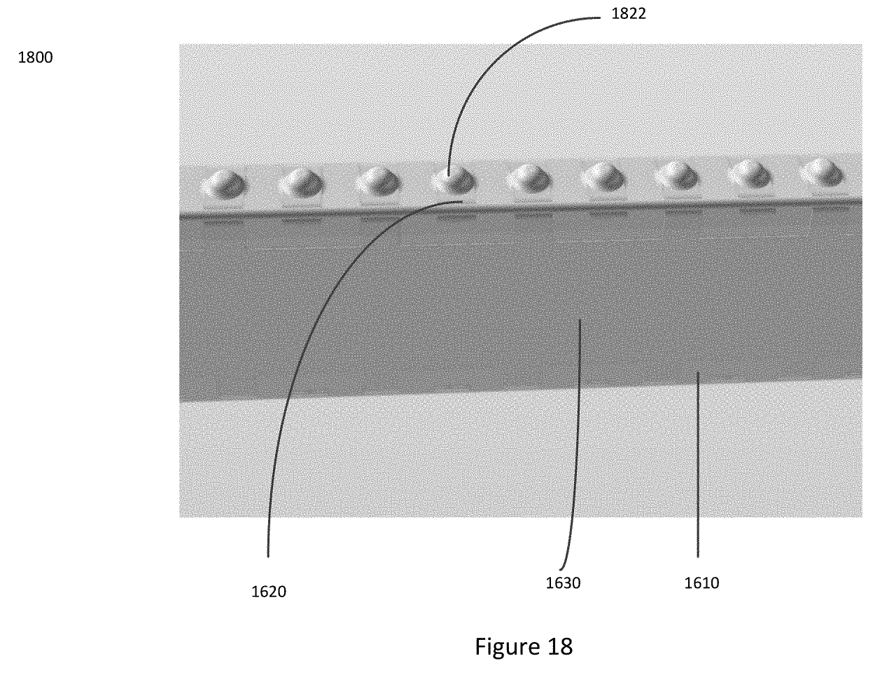

FIG. 18 illustrates a side view of a portion of the frame of FIG. 16. In this example, frame 1610 may include signal pin 1620 as before in FIG. 16. A domed structure 1822 may be formed as part of frame 1610. That is, domed structure 1822 may be molded along with the other portions of frame 1610. This domed structure 1822 may improve a strength of pin 1620. The dome structure 1822 may help to reduce an amount of solder that would otherwise be displaced when frame 1610 is soldered to top printed circuit board 210 and bottom printed circuit board 220. The domed structures 1822 may also reduce stress on frame 1610. An interconnect trace may be formed on top of the bump when the domed structure 1822 and frame 1610 are formed of LDS. Side ground plating may be used to form ground shield layers 1630.

In these and other embodiments of the present invention, other structures capable of supporting very high-speed signals through a frame or as a standalone or other structure, may be provided. An example is shown in the following figure.

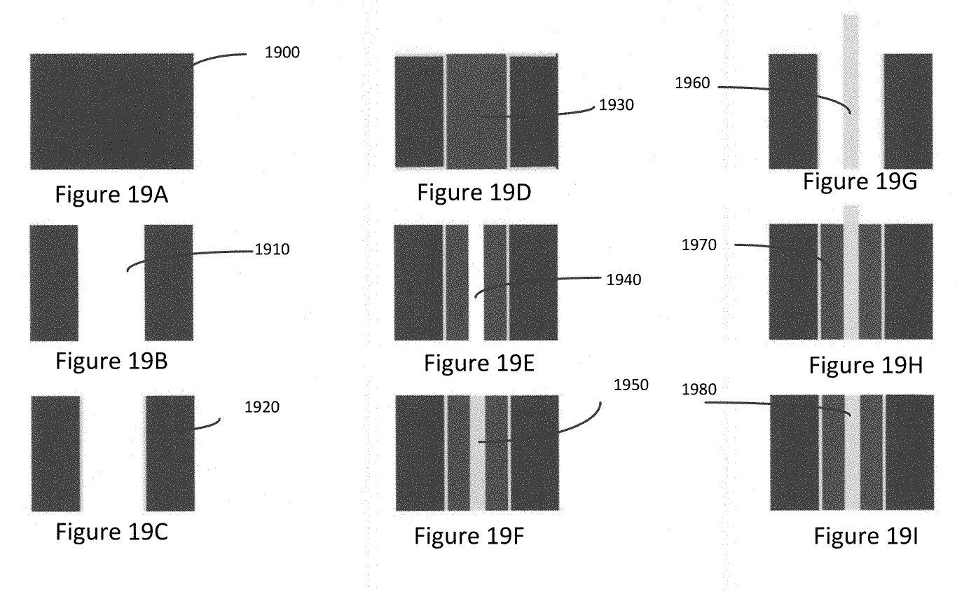

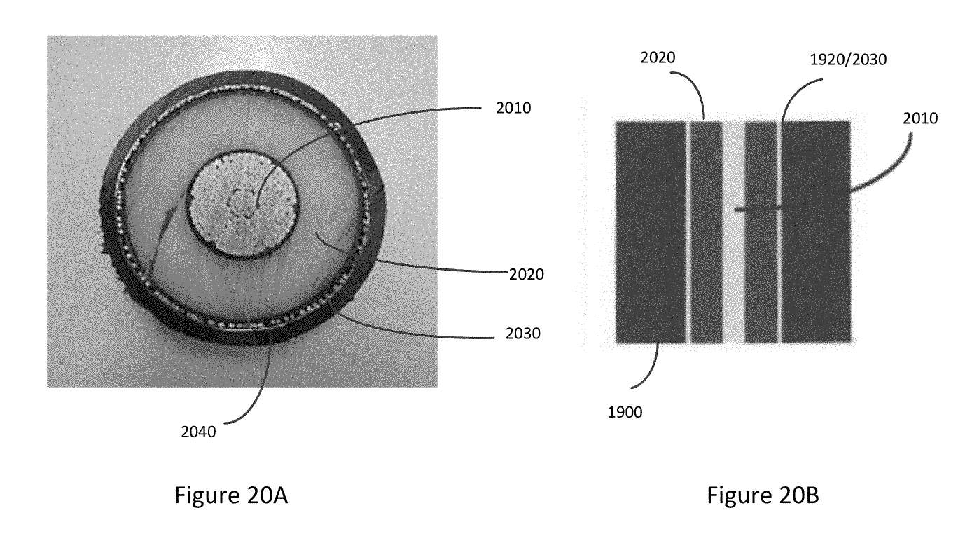

FIGS. 19A-19I and 20A-20B illustrate methods of manufacturing a high-speed path according to an embodiment of the present invention. These high-speed paths may be located in a frame, they may be standalone structures, or they may be used in other ways.

In FIG. 19A, an LDS block 1900 is provided. In FIG. 19B, passage or opening 1910 may be drilled using a laser. This may activate the inside surface for forming a layer of plating 1920 in FIG. 19C.

From this point, at least three different methods may be used. For example, in FIG. 19D, LDS or hot melt molding 1930 may be used to fill opening 1910. In FIG. 19E, second laser drilling may form opening 1940 which again may activate inside surface. Plating 1950 may then fill opening 1940 to complete the structure as shown in FIG. 19F.

In this example, plating 1915 may convey a signal. Plating 1950 may be surrounded by plating 1920, which may be circular or have another shape. Plating 1920 may be grounded to provide a shield for plating 1950.

Alternatively, after FIG. 19C, a conductive core 1960 may be inserted in opening 1910, in FIG. 19G. In FIG. 19H, molding 1970 may fill the gap between conductive core 1960 and plating 1920. Conductive core 1960 may be trimmed to form signal pathways 1980 to complete the structure shown in FIG. 19I.

In this example, signal pathway 1980 may convey a signal. Signal pathway 1980 may be surrounded by plating 1920, which may be circular or have another shape. Plating 1920 may be grounded to shield signal pathway 1980.

In FIG. 20A, a section of a coaxial cable may be formed. This section may include central conductor 2010, dielectric or insulation 2020, shield 2030, and outside insulation layer 2040. Outside insulation layer may be removed. The remaining cable portion may be inserted in the frame portion of FIG. 19C, such that shield 2030 contacts plating 1920 on an inside of passage or opening 1910.

In FIG. 20B, central conductor 2010 may convey a signal. Central conductor 2010 may be surrounded by shield 2030 and plating 1920, which may be circular or have another shape. Plating 1920 and shield 2030 may be connected to ground in order to shield central conductor 2010. This coaxial connector may be housed in LDS block 1900, which may be located in a frame, in a standalone structure, or which may be used in other ways.

The techniques of FIGS. 19 and 20, and similar techniques, may be used to form other structures. An example is shown in the following figure.

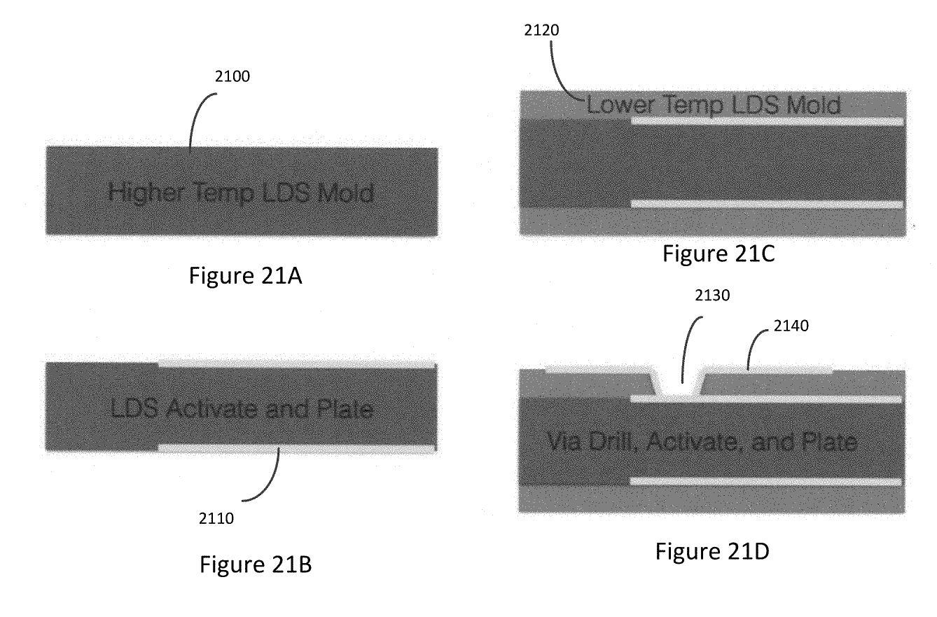

FIGS. 21A-21D illustrate a method of forming interconnect according to an embodiment of the present invention. This interconnect may be used as a portion of a frame, as a standalone structure, or in other ways. In FIG. 21A, an LDS block 2100 may be provided. In FIG. 21B, portions of a top surface a bottom surface of the block may be activated and plated, resulting in plating 2110. A second LDS mold 2120 may be formed on a top and bottom of block 2100, in FIG. 21C. This second LDS mold may be a lower temperature material to prevent destruction of block 2100 during the formation of mold 2120. In FIG. 21D, a trench 2130 may be formed through the second LDS mold 20. This portion of the surface may be plated with plating 2140 to provide a contact from plating 2140 to lower plating 2110.

It should be noted that while the interconnect structures described above are well-suited to forming system-in-package modules, in these other embodiments of the present invention, other types of electronic devices may be formed using these techniques.

In various embodiments of the present invention, contacts, interconnect paths, and other conductive portions of SIP modules may be formed by stamping, metal-injection molding, machining, micro-machining, ink-jet, 3-D, aerosol-jet, or other type of printing, or other manufacturing process. The conductive portions may be formed of stainless steel, steel, copper, copper titanium, phosphor bronze, or other material or combination of materials. They may be plated or coated with nickel, gold, or other material. The nonconductive portions may be formed using injection or other molding, ink-jet, 3-D, aerosol-jet, or other type of printing, machining, or other manufacturing process. The nonconductive portions may be formed of silicon or silicone, rubber, hard rubber, plastic, nylon, liquid-crystal polymers (LCPs), plastic, epoxy, resin, or other nonconductive material or combination of materials. The printed circuit boards used may be formed of FR-4, BT or other material. Printed circuit boards may be replaced by other substrates, such as flexible circuit boards, in many embodiments of the present invention, while flexible circuit boards may be replaced by printed circuit boards in these and other embodiments of the present invention.

Embodiments of the present invention may provide SIP modules that may be located in various types of devices, such as portable computing devices, tablet computers, desktop computers, laptops, all-in-one computers, wearable computing devices, cell phones, smart phones, media phones, storage devices, portable media players, navigation systems, monitors, power supplies, adapters, remote control devices, chargers, and other devices.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

1. A system-in-package module comprising:
a top printed circuit board;
a first component and a first plurality of contacts on a surface of the top printed circuit board;
a bottom printed circuit board;
a second component and a second plurality of contacts on a surface of the bottom printed circuit board, where the surface of the top printed circuit board and the surface of the bottom printed circuit board face each other such that the first component and the second component are between the top printed circuit board and the bottom printed circuit board; and
a frame formed of another printed circuit board and attached to the surface of the top printed circuit board and the surface of the bottom printed circuit board.

2. The system-in-package module of claim 1 further comprising an intermediate layer between the top printed circuit board and the bottom printed circuit board.

3. The system-in-package module of claim 1 wherein the frame is around the first component and the second component.

4. The system-in-package module of claim 1 wherein the frame is located along an edge of bottom printed circuit board.

5. The system-in-package module of claim 1 wherein a first contact in the first plurality of contacts is electrically connected to the first component through a first trace on the top printed circuit board, wherein a second contact in the second plurality of contacts is electrically connected to the second component through a second trace on the bottom printed circuit board, and wherein the frame includes a first interconnect to connect the first contact to the second contact.

6. The system-in-package module of claim 5 wherein the first interconnect is a via through the frame.

7. (canceled)

8. (canceled)

9. A system-in-package module comprising:
a top printed circuit board;
a first component and a first plurality of contacts on a surface of the top printed circuit board;
a bottom printed circuit board;
a second component and a second plurality of contacts on a surface of the bottom printed circuit board, where the surface of the top printed circuit board and the surface of the bottom printed circuit board face each other such that the first component and the second component are between the top printed circuit board and the bottom printed circuit board; and
a high-speed path attached to the surface of the top printed circuit board and the surface of the bottom printed circuit board, wherein the high-speed path is in a frame formed of another printed circuit board, the frame attached to the surface of the top printed circuit board and the surface of the bottom printed circuit board.

10. The system-in-package module of claim 9 wherein the high-speed path is a coaxial structure.

11. (canceled)

12. The system-in-package module of claim 10 wherein the coaxial structure comprises a central conductor and a shield around the central conductor.

13. The system-in-package module of claim 12 wherein the central conductor is a pin.

14. The system-in-package module of claim 12 wherein the central conductor is formed by plating.

15. The system-in-package module of claim 9 wherein the high-speed path comprises a signal pin and two ground pins in the frame, wherein the two ground pins are located on each side of the signal pin.

16. The system-in-package module of claim 15 wherein the high-speed path further comprises ground shielding on an inside edge of frame and an outside edge of the frame.

17. The system-in-package module of claim 15 wherein the signal pin further comprises a domed-shaped conductive structure on a top surface.

18-20. (canceled)

21. A system-in-package module comprising:
a top printed circuit board;
a first component and a first plurality of contacts on a surface of the top printed circuit board;
a bottom printed circuit board;
a second component and a second plurality of contacts on a surface of the bottom printed circuit board, where the surface of the top printed circuit board and the surface of the bottom printed circuit board face each other such that the first component and the second component are between the top printed circuit board and the bottom printed circuit board; and
a printed circuit board frame formed of another printed circuit board and attached to the surface of the top printed circuit board and the surface of the bottom printed circuit board, the printed circuit board frame comprising a plurality of interconnect paths connecting the first plurality of contacts and the second plurality of contacts.

22. The system-in-package module of claim 21 wherein the printed circuit board frame is around the first component and the second component, the printed circuit board frame comprising a shield layer on an outside surface.

23. The system-in-package module of claim 22 wherein a first contact in the first plurality of contacts is electrically connected to the first component through a first trace on the top printed circuit board, a second contact in the second plurality of contacts is electrically connected to the second component through a second trace on the bottom printed circuit board, the plurality of interconnect paths includes a first interconnect path to connect the first contact to the second contact, and the plurality of interconnect paths are formed of vias through the printed circuit board frame.

24. The system-in-package module of claim 1 wherein the region between the top printed circuit board, the bottom printed circuit board, and the frame is encapsulated.

25. The system-in-package module of claim 9 wherein the region between the top printed circuit board, the bottom printed circuit board, and the frame is encapsulated.

26. The system-in-package module of claim 21 wherein the region between the top printed circuit board, the bottom printed circuit board, and the printed circuit board frame is encapsulated.
